(19) United States
(12) Patent Application Publication
(10) Pub. No.: US 2018/0190549 A1
(43) Pub. Date: Jul. 5, 2018

(54) SEMICONDUCTOR WAFER WITH SCRIBE LINE CONDUCTOR AND ASSOCIATED METHOD

(71) Applicants: John Jude O'Donnell, Quin (IE); Colin G. Lyden, Baltimore (IE); Shane Geary, Sixmilebridge (IE); Jonathan Ephraim David Hurwitz, Edinburgh (GB); Brian Beucler, Norwood, MA (US)

(72) Inventors: John Jude O'Donnell, Quin (IE); Colin G. Lyden, Baltimore (IE); Shane Geary, Sixmilebridge (IE); Jonathan Ephraim David Hurwitz, Edinburgh (GB); Brian Beucler, Norwood, MA (US)

(21) Appl. No.: 15/395,404

(22) Filed: Dec. 30, 2016

(51) Int. Cl. H01L 21/66; H01L 23/544

(52) U.S. Cl. CPC H01L 22/32; H01L 22/14; H01L 23/544

(57) ABSTRACT

A semiconductor wafer is provided that includes at least two integrated circuits (ICs); a scribe line extends adjacent to the at least two ICs; and a first conductor extends within the scribe line and is electrically coupled to the at least two ICs.

### BACKGROUND

During integrated circuit manufacture, a great many integrated circuit (IC) die are formed on a single semiconductor wafer. The ICs are arranged in a grid pattern with scribe lines running between them. After the ICs have been fabricated upon the semiconductor wafer, the wafer is cut along the scribe lines in a process called “singulation”, to separate the individual ICs for subsequent packaging and use.

Several levels of tests are performed during IC manufacture. Wafer-level process control tests are performed on test circuits to test whether an IC manufacturing process actually produces circuits that satisfy manufacturing process requirements. Often, process control test circuits are formed within scribe lines for use during manufacturing process testing. For example, a process control test circuit often includes a test transistor device formed within a scribe line. Wafer-level IC tests are performed on individual ICs before cutting the wafer to separate the individual ICs for packaging. Wafer-level IC testing is used to identify and discard defective ICs before incurring the cost of packaging and further testing. Wafer-level testing also is used to efficiently calibrate a large number of ICs for operation at different temperatures by heating an entire wafer with the ICs formed on it to each of multiple different temperatures and by calibrating each IC to operate properly at each different temperature. Individual IC-level functional tests often are performed after the ICs have been singulated and packaged.

Individual ICs include electrical contact pads that are used both for wafer-level testing before singulation and packaging of the ICs and for additional testing and operational use after packaging. An IC testing device typically includes probe contacts to contact the IC contact pads on individual ICs to provide test stimulus signals to the ICs and to receive test results signals from the ICs. During wafer-level testing, the contact pads receive test stimulus signals provided by one or more needle-like probe contacts of the external testing device and provide test results signals to the testing device via the probe contacts. The ICs on a wafer generally are tested one at a time or in small groups. In either case, probe contacts ordinarily are brought into physical and electrical contact with contact pads of each individual IC or groups of ICs to be tested. Several probe contact test passes across a wafer may be required to conduct all required tests. For example, a separate test pass may be required at each of multiple different temperatures. Each testing of an IC or a group of ICs requires an alignment process to align individual probe contacts for physical and electrical contact with individual IC contact pads. As a result, wafer-level IC testing can be a time consuming process.

### SUMMARY

A semiconductor wafer is provided in which conductors extend within scribe lines. The scribe lines extend adjacent to integrated circuits (ICs) disposed upon the wafer. Signals may be provided to the ICs over the conductors within the scribe lines.

In one aspect, a semiconductor wafer includes first and second ICs and a scribe line extending between them. A metal conductor extends within the scribe line and is electrically coupled with at least one of the first and second ICs.

In another aspect, a semiconductor wafer includes a plurality of ICs arranged in a two dimensional grid including a plurality of rows of ICs and a plurality of columns of ICs. A plurality of first scribe lines each extends adjacent to multiple ICs in adjacent rows of ICs. A plurality of second scribe lines each extending adjacent to multiple ICs within adjacent columns of ICs. A plurality of first conductors each extends adjacent to multiple ICs within a first scribe line.

In another aspect, a method of wafer-level testing of integrated circuits is provided that includes conducting an electronic signal between a metal conductor within a scribe line and an integrated circuit.

### BRIEF DESCRIPTION OF THE DRAWINGS

FIG. 1 is an illustrative drawing showing a portion of a wafer that includes a large number of integrated circuits arranged in a two-dimensional grid pattern in which scribe lines demarcate boundaries between ICs.

FIG. 2 is an illustrative enlarged, cross-sectional view of a portion of the semiconductor wafer of FIG. 1 showing a scribe line extending between adjacent ICs.

FIG. 3A is an illustrative drawing representing on-chip circuits involved with wafer-level test disposed within individual ICs and signal conductors located within scribe lines formed on the semiconductor wafer of FIG. 1.

FIG. 3B is an illustrative drawing representing alternative on-chip circuits involved with wafer-level test disposed in part within individual ICs and in part within scribe lines formed on an alternative embodiment of the semiconductor wafer of FIG. 1.

FIG. 4 is an illustrative flow diagram representing an IC test process that sends and receives wafer-level test signals, across scribe lines.

FIG. 5A is an illustrative top view of a wafer that includes a large number of example reticle exposure regions arranged in a two-dimensional grid pattern.

FIG. 5B is an enlarged view of an example reticle exposure region of the wafer of FIG. 5A.

FIG. 6 is an illustrative perspective view of the wafer including multiple wafer-level test pad grid locations that each includes multiple wafer-level test contact pads and a testing device with test probes contacting certain wafer-level test contact pads.

FIG. 7 is an illustrative drawing showing an alternate embodiment of layout of scribe line conductor paths and wafer-level test pad grid locations within a reticle exposure region.

FIG. 8 is an illustrative flow diagram representing a process to identify a defective IC within a reticle exposure region.

FIG. 9 is an illustrative block diagram showing details of a portion of the wafer 100 of FIG. 1.

### DESCRIPTION OF EMBODIMENTS

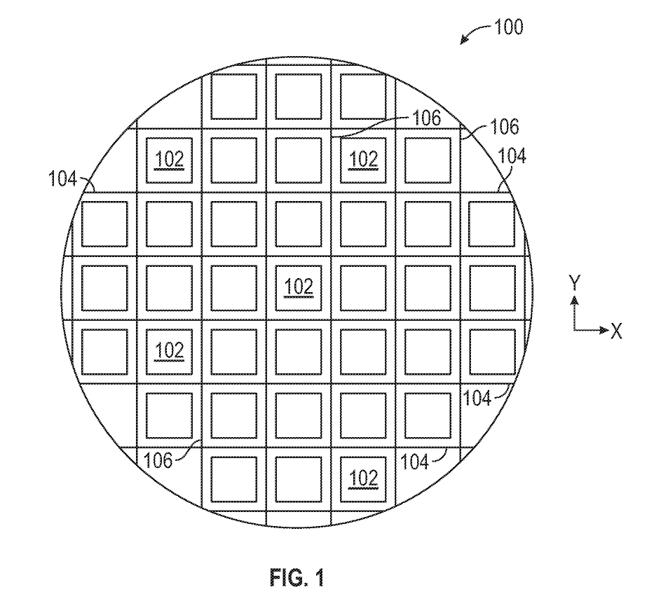

FIG. 1 is an illustrative drawing showing a portion of a wafer 100 that includes a large number of integrated circuits (ICs) 102 arranged in a two-dimensional grid pattern in which scribe lines 104, 106 demarcate boundaries between ICs. Multiple first scribe lines 104 extend parallel to a first axis (e.g., horizontal x axis) and multiple second scribe lines extend parallel to a second axis (e.g., vertical y axis) 106, which is perpendicular to the first axis. The first and second scribe lines 104, 106 define a two-dimensional scribe line grid pattern in which each IC 102 is bounded by two first scribe lines 104 and is bounded by two second scribe lines 106. During wafer level testing, power signal, control signals, and reference signals produced by an off-chip testing device (not shown) are propagated across scribe lines 104 and/or scribe lines 106 to reach all of the ICs on the wafer 100.

In some embodiments, a scribe line 104, 106 includes elongated slots, grooves, or openings provided through layers formed over a substrate. In some embodiments the scribe lines are filled with a material such as silicon dioxide, thereby creating a scribe line having a physical structure. Alternatively, in some embodiments, scribe lines include an elongated raised area or mesa structure. The scribe lines 104, 106 can be produced concurrently with the formation of each of the ICs 102.

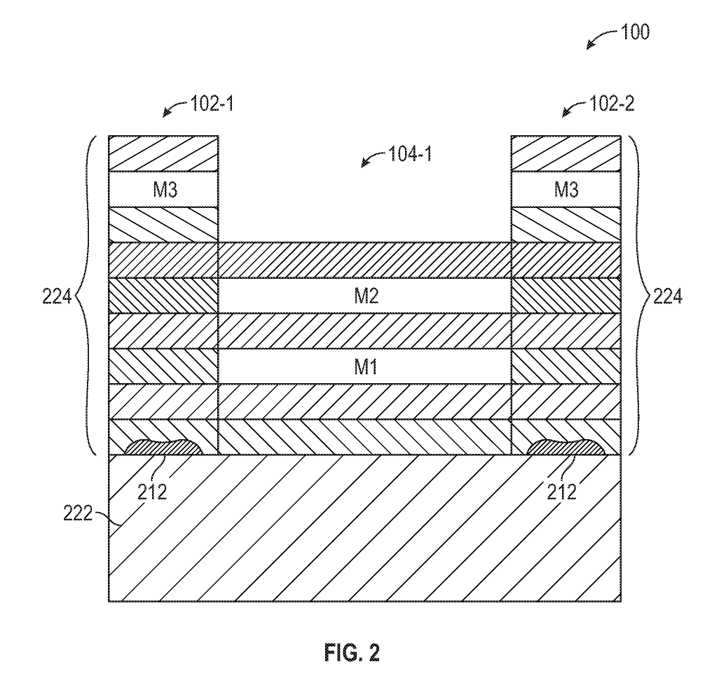

FIG. 2 is an illustrative example, cross-sectional view of a portion of the semiconductor wafer 100 of FIG. 1 showing a cross-sectional view of a portion of a first scribe line 104-1 extending between adjacent ICs 102-1, 102-2 on opposite sides of the scribe line portion 104-1. The scribe line portion 104-1 includes a first metal conductor layer (M1) and a second metal conductor layer (M2) to extending within scribe line 104-1 to conduct one more of control signals, a power signal, and a reference signal of an IC as. In some embodiments, one or more metal conductors M1, M2 extend directly across a scribe line to couple together ICs located adjacent to each other on opposite sides of a scribe line. In some embodiments metal conductors that extend along a portion of the length of a scribe line so as to couple non-adjacent ICs.

The semiconductor wafer 100 provides a substrate region 222 upon which multiple layers 224 are deposited during IC manufacture to produce the ICs. In some embodiments, the layers 224 alternate between conductive type layers and insulating type layers. The ICs include circuit structures 212 such as transistor device structures. A particular layer can include several sub-layers, e.g., a conducting layer can comprise several conducting sub-layers, such as an aluminum layer over a titanium-tungsten alloy layer, and insulating type layers can comprise several sub-layers such as a plasma enhanced chemical vapor deposition (PECVD) layer, a spin-on-glass (SOG) layer, or other layer over an oxide layer, for example.

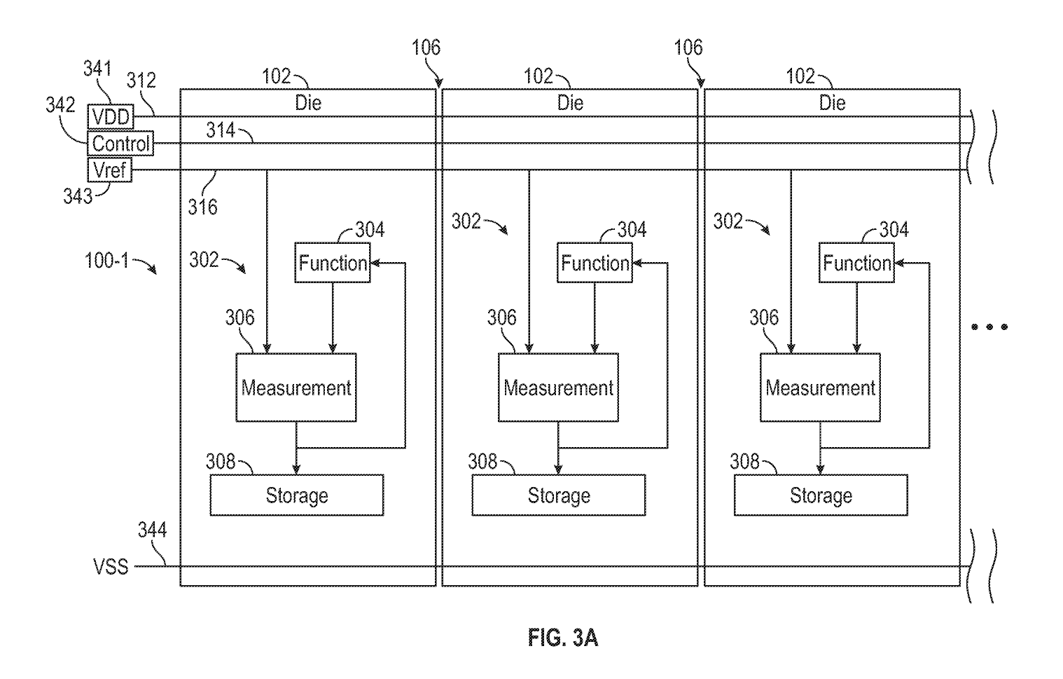

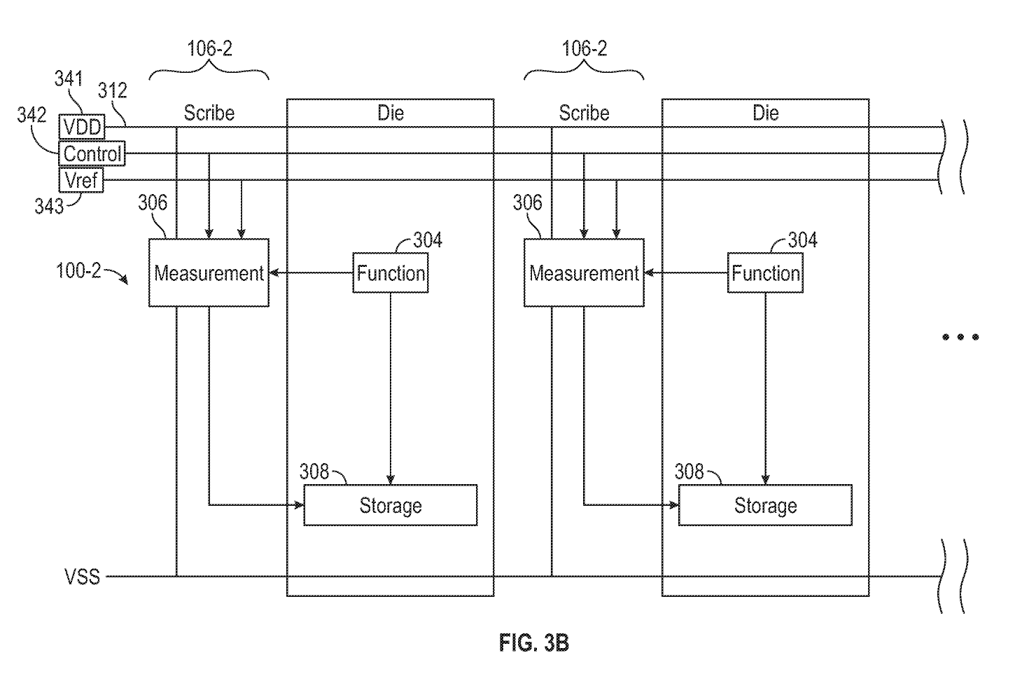

FIG. 3A is an illustrative drawing representing a wafer portion 100-1 that includes three ICs 102 that each includes on-chip circuits 302 involved with wafer-level testing. In the example wafer portion 100-1, each IC 102 includes on-chip circuitry 302 that is powered and controlled using signals provided on signal conductor lines 341-343 that extend within scribe lines 106. The signal conductor lines 341-344 couple to on-chip circuitry 302 within individual ICs 102. More specifically, the signal conductor lines couple to on-chip circuitry 302 of multiple ICs 102 that share the signals on conductor lines 341-344. In some embodiments, multiple signal conductor lines 341-344 traverse multiple ICs 102 and traverse multiple scribe lines 106 to deliver shared signals to multiple ICs that are separated from each other by scribe lines 106.

The example on-chip circuits 302 include functional circuitry 304 coupled to measurement circuitry 306 used to test performance of the functional circuitry 304 and storage circuitry 308 used to store measurement results. In some embodiments, an on-chip circuit 302 acts as a test circuit and the storage circuitry 308 stores measurement results that represent calibration values to calibrate performance of the functional circuitry 306 based upon the stored measurements. The measurement circuitry 306 typically measures at least one of voltage or current to determine performance characteristics such as frequency, impedance, gain or linearity, for example. As explained below with reference to FIG. 3B, in some embodiments a portion of an on-chip circuit 302 involved with wafer-level testing that is not used once an IC has been calibrated, such as certain measurement circuitry 304, is disposed within the scribe lines 106.

Variations in chip processing and packaging operations can result in deviations of functional circuits such as analog circuits and sensors from their target specifications. To optimize the performance of the systems in which these components are placed, it often is necessary to “trim” circuitry to meet specifications. A trimming operation compensates for variations in performance of the analog circuits due to manufacturing variances of these components. Alternatively, in some embodiments rather than trim, a record of a measured value is stored for later use to compensate.

More specifically, in the example shown, the functional circuitry 304 includes a bandgap reference (BGR), the measurement circuitry 306 includes a trimming logic circuit configured to implement one or more trimming algorithms, and the storage circuitry 308 includes a trim value storage circuit. A BGR typically is used as voltage reference that is insensitive to variations of temperature, supply voltage, and process parameters. A BGR typically is calibrated through a trimming process for proper operation at different temperatures. Trimming of the illustrative BGR functional circuitry 304 is controlled by an algorithm executed using the trimming logic measurement circuitry 304. The trimming logic measurement 306 circuitry may be configured to execute one or more of a variety of trimming algorithms that are operable to determine calibration values for use to adjust values of reference trim bits used in trimming the BGR functional circuitry 304. In some embodiments, trimming involves one-time programming in which the trim storage includes fuses that are usually cut or uncut, and/or by programming a one-time programmable dedicated memory such as a ROM. In other embodiments, trimming involves multi-time programming in which the trim storage 308 includes Flash storage that can be reprogrammed multiple times. A set of ‘trim bits’ is selected based upon results of the trimming algorithm to indicate which fuses to cut and which fuses to leave uncut and/or which memory bits to set in a dedicated ROM or in Flash storage.

A voltage power conductor line 312, control signal conductor lines 314 and reference signal conductor line 316 extend across the wafer portion 100-1 from one IC 102 to the next and extend across the scribe lines 106 so as to reach all of the ICs 102 of the wafer portion 100-1. The voltage power conductor 312 is coupled to receive a voltage power signal from an off-chip source such as a tester (described below) via one or more first test pads 341. The control signal conductors 314 are coupled to receive a control signals from an off-chip source via one or more second test pads 342. The control signals may be included to provide clock signals. Moreover, control lines may be included to provide measurement results signals to a tester circuit described more fully below. The reference signal conductors 316 is coupled to receive a reference signal from an off-chip source via one or more second test pads 343. In some embodiments, the power 312, control lines 314 and reference line 316 extend within individual ICs 102 and cross scribe lines 106 to go from one IC to the next so as to simultaneously provide the voltage, reference and control signals to the test circuits 302 of multiple ICs 102. In operation, a voltage power signal (V_{DD}) is provided to the on-chip circuits 302 on a power signal conductor lines 312 that extend across ICs 102, from one IC to the next, and that extend across the scribe lines 106. The wafer acts 100 as a ground voltage potential. Similarly control signals are provided on control signal conductor lines 314 that extend across the ICs 102 and across the scribe lines 106, and reference signals are provided on reference signal line 316 that extend across the ICs 102 and across the scribe lines 106.

In operation, the control signals on the control signal lines 314 initiate execution of the trimming algorithm, thereby initiating a trimming process. The reference signal on line 316 provides a reference voltage value at which the BGR should operate for a given temperature. The trimming logic circuitry 306 is configured to compare a voltage produced by the BGR 304 with the provided reference voltage value under alternative possible trim configurations to determine which trim configuration results in the BGR 304 providing a desired voltage level. A calibration value determined based upon the trim algorithm is stored in the trim storage 308. The trimming process may be performed at each of multiple different temperatures.

In some embodiments, the functional circuitry 304 includes a sensor, such as a temperature sensor, gas sensor or accelerometer. External stimuli are imparted to the sensor and a sensor value produced by the sensor in response to stimuli is used to calibrate the sensor. In the alternative embodiment no measurement circuit is required. A calibration produced based upon the stimuli is stored to the measurement circuit 308.

FIG. 3B is an illustrative drawing representing a wafer portion 100-2 that includes three ICs 102-2 that each includes on-chip functional circuitry 304, on-chip measurement circuitry 306 and on-chip storage circuitry 308 that involved with wafer-level testing and/or calibration. In the example wafer portion 100-2, each IC 102-2 the on-chip functional circuitry 304, measurement circuitry 306 and storage circuitry 308 are powered and controlled using signals provided on shared lines that extend within scribe lines 106-2. A portion of the on-chip circuitry, specifically the measurement circuitry 306, is disposed within the scribe lines 106-1. The operation of the functional circuitry 304, on-chip measurement circuitry 306 and on-chip storage circuitry 308 is explained above with reference to FIG. 3A.

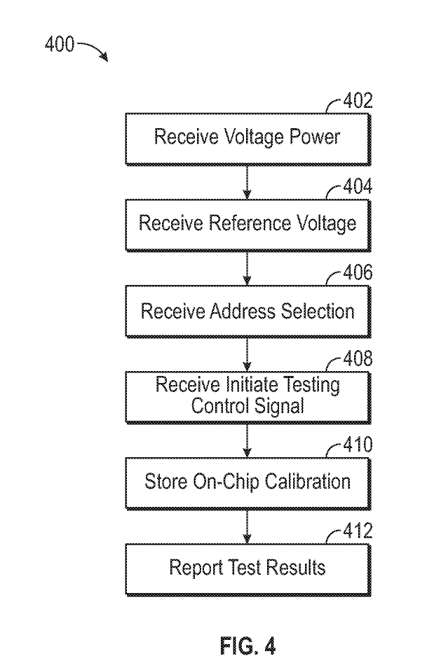

FIG. 4 is an illustrative flow diagram representing an on-chip IC test process 400 that sends and receives wafer-level test signals, across scribe lines. The process 400 is explained with reference to the wafer portion 100-1 of FIG. 3A. It will be appreciated that the same process also may be used with the wafer portion 100-2 of FIG. 3B. In block 402, a power signal is received on the first test pad 341 and is provided via power line 312 that extends within a scribe line 106 to power the test-related circuits 302. In block 404, a reference signal (V_{ref}) is received on the second test pad 342 and is provided via reference signal line 316 that extends within a scribe line 106 for use in testing functional circuits 304 of the ICs 102 of the wafer portion 100-1. In block 406, a chip address selection control signal is received via the third test pad 343 and is provided via control lines 314 that extends within a scribe line 106 and that addresses trimming logic measurement circuits 306 of a one or more ICs 102 of the wafer portion 100-2. In response to a matching chip select address signal received on control lines 314, block 408, causes the logic circuitry 306 to initiate a trim algorithm. In block 410, the storage circuits 308 of the currently addressed ICs 102 store the test results. In block 412, the logic circuit 306 sends test a results signal via control signal lines 314 and the third test pad 343 to a testing device (not shown) to indicate whether the BGR 304 has been successfully trimmed.

A semiconductor IC manufacture process used to produce a wafer 100 of FIGS. 1-2 involves formation of the multiple layers 224 upon a wafer. More particularly, manufacture of the ICs 102 typically involves a photolithography process. During formation of a typical IC layer 224, the wafer 100 is coated with a photoresist material. A photomask, commonly referred to as a reticle (not shown), is selected that defines an image projection pattern used to create geometric shapes within the layer. The reticle includes opaque regions that are non-transparent to given radiation wavelengths and blank regions that are transparent at the given radiation wavelengths. A light “radiation” source shines light onto the reticle and an image defined by the opaque and blank regions is projected through a lens system onto a reticle exposure region on the wafer surface. The reticle thereby allows selective exposure of certain portions of the photoresist coating to the radiation and selective blocking of exposure of other areas to the radiation. Following the reticle image projection and resultant photoresist exposure, the wafer is stepped over to a next reticle exposure region and the projected image of that next reticle is used to determine shapes of physical geometries formed in the layer. This stepping and exposure process continues with the selected reticle until all reticle regions within the die have been exposed. Once the reticle image has been projected onto all regions of the wafer, a physical deposition process deposits material onto the layer according to the photoresist exposure pattern. This process repeats using different reticles for different IC fabrication layers. Thus, a given reticle exposure region of a wafer may be exposed to light through multiple different reticles that correspond to different layers.

In some embodiments, wafer-level testing proceeds on a reticle-by-reticle basis. The testing device provides individual test signals to the wafer-level test contact pads of each individual reticle to power up and test the ICs of that reticle exposure region. Thus, the testing device need only provide a voltage power level sufficient to power the ICs of an individual reticle that are tested together.

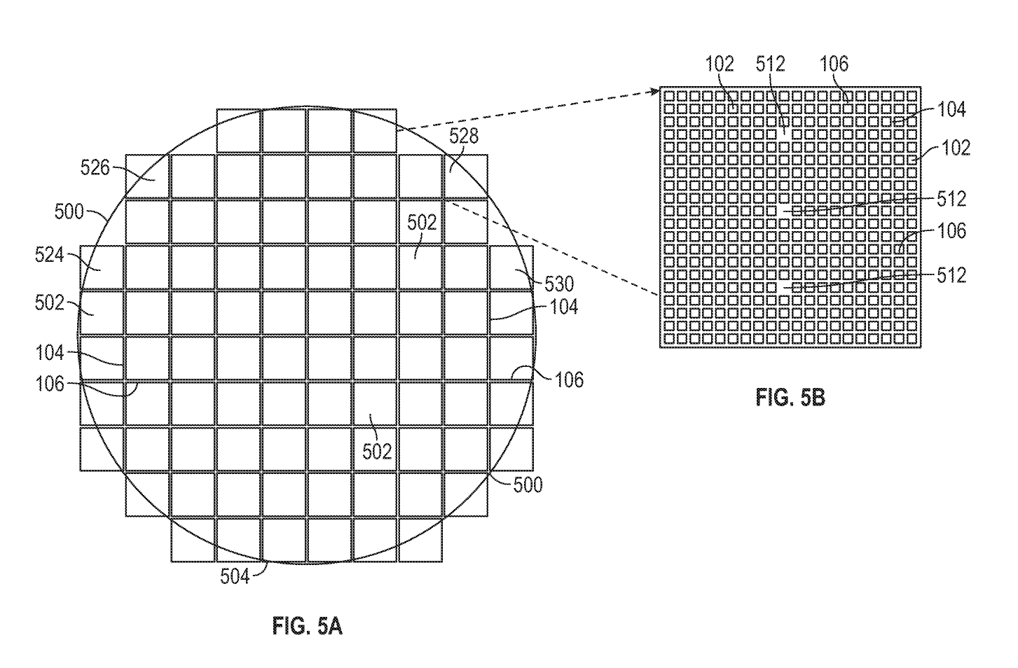

FIG. 5A is an illustrative top view of a wafer 500 that includes a large number of example reticle exposure regions 502 arranged in a two-dimensional grid pattern. The wafer 500 is generally circular in cross-section with an alignment flat 504 for use in aligning the wafer 500 during fabrication of the ICs 102 upon it. FIG. 5B is an enlarged view of an example individual reticle exposure region 502 of the wafer 500 of FIG. 5A that includes a large number of individual integrated circuits 102 arranged in a two-dimensional grid pattern in which vertical and horizontal scribe lines 104, 106 demarcate boundaries between the ICs 102. Each reticle exposure region 502 encompasses a portion of a surface of the wafer 500 and that includes multiple ICs 102. The wafer 500 includes a multiplicity of reticle exposure regions 502.

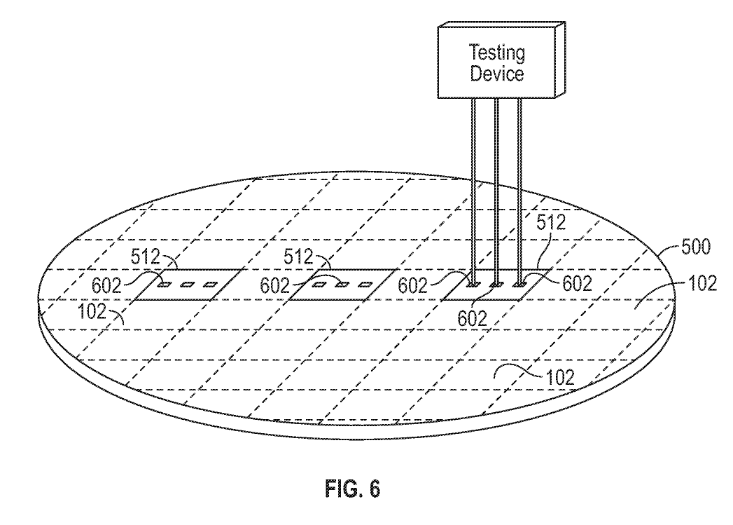

Referring to FIG. 5B, the example wafer reticle exposure region includes a two-dimensional grid of ICs 102 with first (vertical) scribe lines 104 extending between adjacent rows of ICs 102 and with second (horizontal) scribe lines 106 extending between adjacent columns of ICs 102. In one embodiment, wafer-level test contact pads, shown in FIG. 6 discussed below, are provided at multiple wafer-level test pad grid locations 512 within the example reticle exposure region 502. Signal conductors (not shown) extend within the scribe lines 104, 106 to components of test and/or calibration circuits disposed within individual ICs 102 and/or disposed within scribe lines 104, 106. That is, wafer-level test contact pads, rather than ICs 102, are formed at these multiple test pad grid locations 512, which are surrounded on four sides by ICs 102. Since the wafer-level test contact pads are used only for wafer-level testing, they need not be sized small enough to be packaged within a packaged IC, and therefore, they can have physically larger dimensions than electrical contact pads disposed on the individual ICs. Testing device probe contacts can be more easily and quickly aligned with such larger dimension wafer-level test contact pads to thereby speed wafer-level testing.

FIG. 6 is an illustrative perspective view of the wafer 500 including multiple wafer-level test pad grid locations 512 that each includes multiple wafer-level test contact pads 602. Individual ICs 102 are indicated within dashed lines. A testing device 622 is shown that includes test probes 624. The test probes 624 are shown in physical contact with the wafer-level test contact pads 602 of one of the wafer-level test pad grid locations 512. In operation, test control and/or stimulus signals and test results signals are communicated via the contact pads 602 and the test probes 624 to and from ICs 102 of the wafer 500. As explained above, the test control and/or stimulus and results signals are communicated from one IC 102 to the next via conductors that extend within scribe lines between ICs 102. It can be appreciated that, if appropriate, testing can also be done using the pads in the active ICs in which case dedicated wafer level test contact pads may not be required.

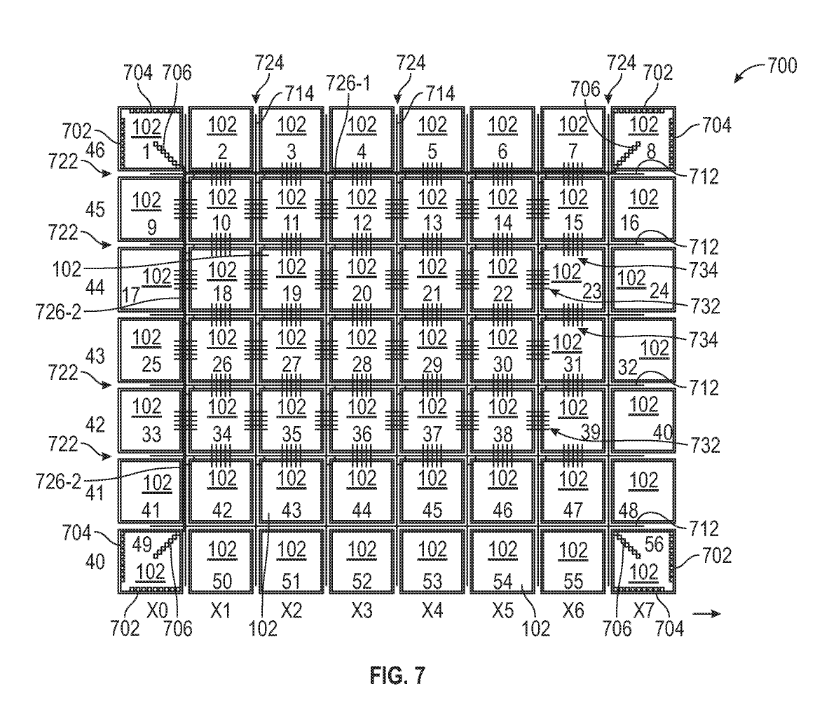

FIG. 7 is an illustrative drawing showing an alternative reticle exposure region 700 of a wafer. The reticle exposure region 700 includes fifty-six ICs 1021-10256 disposed in seven rows of IC grid locations labeled Y0 to Y6 and includes eight columns of IC grid locations labeled X0 to X8 as shown. Individual ICs are labeled 1 through 55. Corner grid locations (X0, Y0), (X0, Y6), (X7, Y0), and (X7, Y6) contain first, second and third wafer-level test contact pads 702, 704, 706. The first wafer-level test contact pads 702 provide a voltage power signal. The second wafer-level test contact pads 704 provide a chip enable signal. The third wafer-level test contact pads 704 provide I/O control signals. The remaining grid locations contain identical ICs to be tested. Referring to FIG. 5A, for example, it will be appreciated that locating the wafer-level test contact pads near the four corners of the reticle exposure region ensures that portions of the wafer that are only partially exposed to a reticle, such as regions 524, 526, 528 and 530, include a wafer-level test contact pad so that ICs in such partial regions can be tested.

The first wafer-level test contact pads 702 are coupled to each of multiple first scribe line conductors 712, which extend in a first (horizontal) direction along a length within each of multiple first (horizontal) scribe lines 722 to communicate a voltage power signal to the ICs 102 to selectably power up the ICs for testing. The IC substrate provides ground potential. The second wafer-level test contact pads 704 are coupled to each of multiple second scribe line conductors 714, which extend in a second (vertical) direction along a length within each of multiple second (vertical) scribe lines 724 to an enable control signal used to selectably enable ICs for testing. The third wafer-level test contact pads 706 within the corner grid locations at (X0, Y6) and (X7, Y6) are coupled to one or more third scribe line conductors 726-1 that extend in a first (horizontal) direction along a row of ICs 102 along one edge (e.g. a top) of the reticle exposure region 700. The third wafer-level test contact pads 706 within the corner grid locations at (X0, Y0) and (X7, Y0) are coupled to one or more fourth scribe line conductors 726-2 that extend in a second (vertical) direction along a columns of ICs 102 along one edge (e.g. a left) of the reticle exposure region 700.

Cross-scribe line conductors 732, 734 provide I/O signal paths across scribe lines between adjacent ICs 102 on opposite sides of the scribe lines. First cross-scribe line conductors 732 provide first (horizontal) signal paths between ICs 102 disposed adjacent to each other in different grid columns. Second cross-scribe line conductors 734 provide second (vertical) signal paths between ICs 102 disposed adjacent to each other in different grid rows.

The fourth scribe line conductors 726-2 are coupled to conduct I/O signals to a column of ICs 102 of the reticle exposure region 700. These ICs 102, in turn, communicate the I/O signals to their neighbor ICs via their local first cross-scribe line conductors 732 etc. The third scribe line conductors 726-1 are coupled to conduct I/O signals to a row of ICs 102. These ICs 102, in turn, communicate the I/O signals to their neighbor ICs via their local second cross-scribe line conductors 734 etc. It will be appreciated that communicating I/O signals across scribe lines obviates a need for an address array with address lines extending within the scribe regions.

During wafer-level testing, a power signal provided to contact pads 702 selectably powers the ICs, an enable signal provided to pads 704 selectably enables the ICs, and I/O signals provided on pads 706 selectably provide address, control and results signals. The I/O signals are propagated across scribe lines using cross-scribe line conductors 732 and/or 734 from one IC 102 to the next to communicate address, control and results signals throughout the reticle exposure region 700. The I/O signals include information provided by the testing device that determines the path between ICs.

Certain IC defects can undermine wafer-level testing of other ICs in a reticle exposure region. Since multiple ICs are tested together, a defective IC within a reticle exposure region has the potential to corrupt wafer-level test results for multiple ICs within the region. For example, an IC within the reticle exposure region 700 could have a defect causing a short circuit or an open circuit. If that defective IC is coupled by a testing device to a common power source along with multiple other non-defective ICs within the reticle region during wafer-level testing, then the defective short circuit or open circuit could corrupt test results for the non-defective ICs. Accordingly, ICs with defects that can corrupt testing of other ICs are identified and excluded from wafer-level testing of a reticle exposure region.

In some embodiments, first scribe conductors 712 that extend within first scribe lines 722 and second scribe conductors 714 that extend within second scribe lines 724 can be configured to extend across their respective scribe lines and/or along longitudinal lengths of their respective scribe lines. For example, first scribe line conductors 712 can be configured to extend within a first scribe line selectably couple ICs 30, 37 disposed adjacent to each other and on opposite sides of a first scribe line 722 across the first scribe 722 from each other. Also, for example, first scribe line conductors 712 can be configured to extend within a first scribe line 722 to selectably couple non-adjacent ICs 30, 36 and to selectably couple non-adjacent ICs 30, 37 disposed on opposite sides of a first scribe line 712 across the first scribe 712 from each other. Additionally, for example, first scribe line conductors 712 can be configured to extend within a first scribe line 722 selectably couple adjacent ICs 30, 31 disposed on the same side of a first scribe line 712.

Similarly, for example, second scribe conductors 714 can be configured to extend within a second scribe line 724 to selectably couple ICs 30, 31 disposed adjacent to each other and on opposite sides of a second scribe line 724 across the second scribe line 724. Also, for example, second scribe line conductors 714 can be configured to extend within a second scribe line 724 to selectably couple non-adjacent ICs 30, 23 disposed on opposite sides of a second scribe line 724 across the second scribe 714 from each other and to selectably couple non-adjacent ICs 30, 15. disposed on opposite sides of a second scribe line 724 across the second scribe 714 from each other. Additionally, for example, second scribe line conductors 714 can be configured to extend within a second scribe line 724 to selectably couple adjacent ICs 30, 22 disposed on the same side of a second scribe line 714.

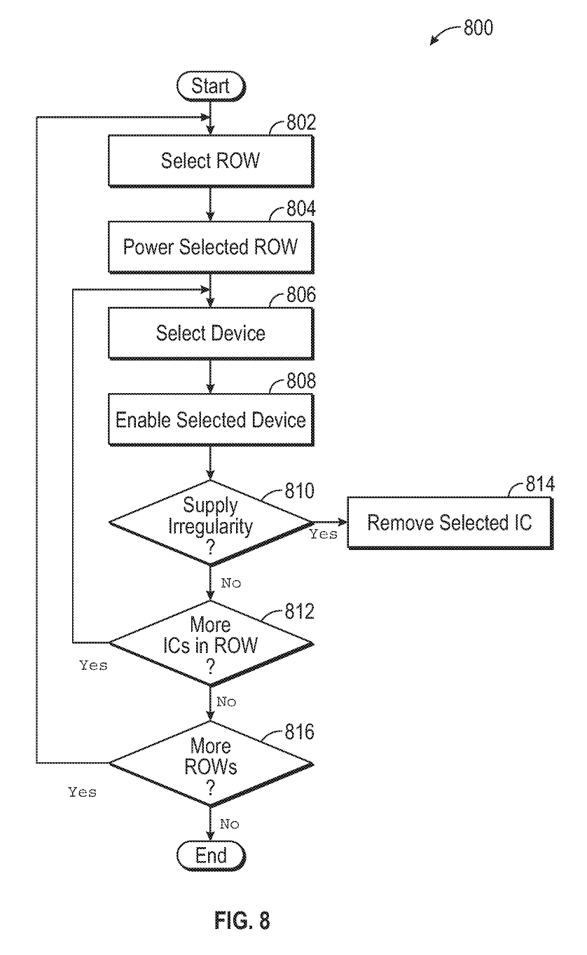

FIG. 8 is an illustrative flow diagram representing a process 800 to identify a defective IC within a reticle exposure region. In block 802, the testing device selects a row of ICs that has not yet been tested for defective ICs. In block 804, the testing device provides a voltage power signal to a first scribe line conductor coupled to power ICs of the presently selected row. In block 806, the testing device selects an IC from the presently selected row that has not yet been tested for a defect. In block 808, the testing device provides an enable signal to a second scribe line conductor coupled to power the presently selected IC of the presently selected row. In decision block 810, the testing device determines whether the presently selected IC exhibits a supply signal irregularity that indicates a defects such as an open circuit or a short circuit. If decision block 810 determines that the presently selected IC exhibits a supply signal irregularity that indicates a defect, then control flows to block 814 in which the testing device operatively removes the defective IC. Following block 814, control flows to decision block 812 following block 814. If block 810 determines that there is no such supply signal irregularity, then control flows directly to decision block 812. Decision block 812 determines whether there are additional ICs in the presently selected row that have not yet been tested. If yes, then control flows back to block 806. If no, then control flows to block 816 and the testing device determines whether there are additional rows that have not yet been tested. If yes, then control flows back to block 802. If no, the process ends.

Operative removal of a defective IC can involve sending a control signal to cause electrical disconnection of the defective IC from a scribe line voltage conductor during wafer-level. Disconnection can include blowing one or more fuses or to open one or more switches to remove a connection between the defective IC and a scribe line voltage conductor. Alternatively, disconnection can include laser cutting of one or more connections between the defective IC and a scribe line voltage conductor.

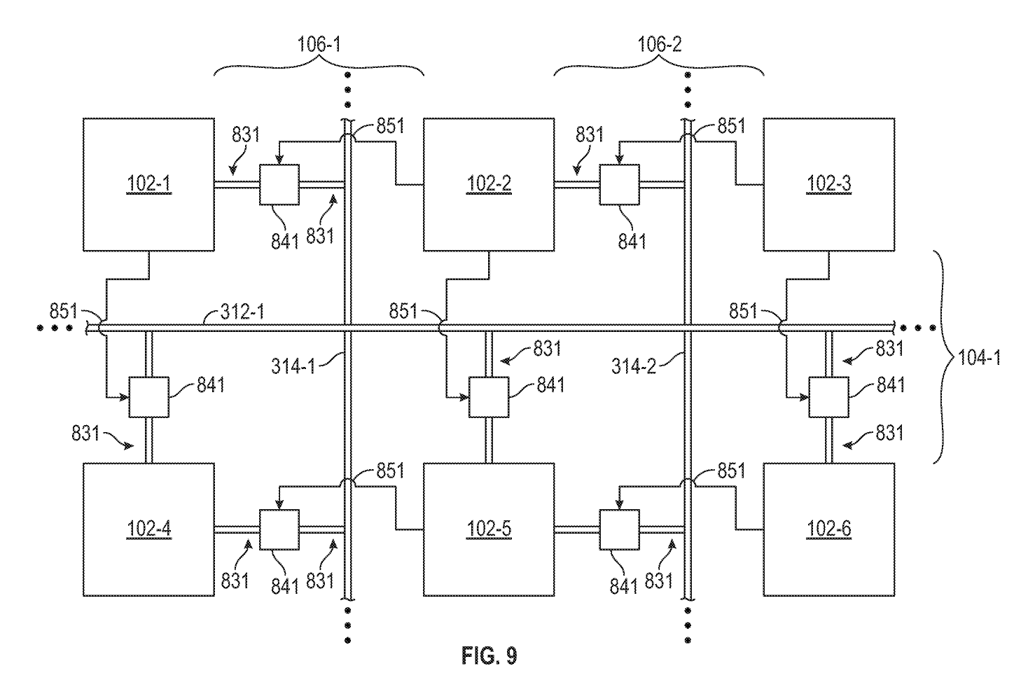

FIG. 9 is an illustrative block diagram showing details of a portion of the wafer 100 of FIG. 1. Six ICs 102-1 to 102-6 are shown with a first scribe line 104-1 and two second scribe lines 106-1, 106-2 extending between them in a grid pattern. ICs 102-1 to 102-6 are shown adjacent to first scribe line 104-1. ICs 102-1, 102-4, 102-2 and 102-5 are shown adjacent to second scribe line 106-1. ICs 102-2, 102-5, 102-3 and 102-6 are shown adjacent to second scribe line 106-2. ICs 102-1 and 102-4 are shown adjacent to each other and disposed on opposite sides of the first scribe line 104-1. ICs 102-1 and 102-2 are shown adjacent to each other and disposed on opposite sides of second scribe line scribe line 106-1. ICs 102-1 and 102-3 are shown non-adjacent to each other and disposed on the same side of the first scribe line scribe line 104-1. ICs 102-1 and 102-6 are shown non-adjacent to each other and disposed on opposite sides of the first scribe line scribe line 104-1.

Individual conductor portions 831, which include selectable switch circuits 841, are disposed to selectably couple individual ICs 102-1 to 102-6 to individual voltage power conductors 312-1, 314-1, 314-2 as shown. Individual switch control lines 851 are coupled to communicate switch select control signals provided by a given IC to selectably couple a different given IC to a voltage power conductor. Thus, for example, switch control signals from a given IC can be used to selectably determine whether a different IC is coupled to a voltage power conductor.

Assume, for example, that decision block 810 determines that first IC 102-1 has a defect requiring its operative removal from wafer-level testing. In block 814, the testing device sends voltage power signals and enable signals to power up and enable the second IC 102-2 while the first IC 102-1 is not powered on. The testing device addresses control signals to the second IC 102-2 causing it to send a switch select control signal over the switch control line 851 disposed within the second scribe line 106-1 extending between the first and second ICs 102-1, 102-2 to selectably electrically disconnect the first IC 102-1 from the voltage power conductor 314-1 to thereby operatively remove the first IC 102-1 from the wafer 100 during wafer-level testing. In some embodiments, the selectable switch circuits 841 include fuse circuits. In some embodiments, the selectable switch circuits 841 include FET switch circuits.

The above description is presented to enable any person skilled in the art to create and use a semiconductor wafer with conductors disposed within scribe lines to simultaneously communicate test signals to and from multiple ICs. Various modifications to the embodiments will be readily apparent to those skilled in the art, and the generic principles defined herein may be applied to other embodiments and applications without departing from the spirit and scope of the invention. In the preceding description, numerous details are set forth for the purpose of explanation. However, one of ordinary skill in the art will realize that the invention might be practiced without the use of these specific details. In other instances, well-known processes are shown in block diagram form in order not to obscure the description of the invention with unnecessary detail. Identical reference numerals may be used to represent different views of the same or similar item in different drawings. Thus, the foregoing description and drawings of embodiments in accordance with the present invention are merely illustrative of the principles of the invention. Therefore, it will be understood that various modifications can be made to the embodiments by those skilled in the art without departing from the spirit and scope of the invention, which is defined in the appended claims.

1. A semiconductor wafer comprising:
a first integrated circuit (IC):
a second IC;
a scribe line extending between the first IC and the second IC; and
a first metal conductor extending within the scribe line electrically coupled with at least one of the first and second ICs.

2. The semiconductor wafer of claim 1 further including:
an on-chip circuit disposed within the first IC;
wherein the first metal conductor couples to the on-chip circuit.

3. The semiconductor wafer of claim 1 further including:
an on-chip circuit disposed within each of the first and second ICs;
wherein the first metal conductor couples to each of the on-chip circuits.

4. The semiconductor wafer of claim 1 further including:
a switch disposed within the scribe line to selectably couple the first metal conductor between the first and second ICs.

5. The semiconductor wafer of claim 1 further including:
a test pad electrically coupled to provide a signal to the first metal conductor.

6. The semiconductor wafer of claim 1 further including:
a test circuit that includes a first circuit component disposed within at least one IC and that includes a second circuit component disposed within the scribe line;
wherein the first metal conductor is electrically coupled to the second circuit component disposed within the scribe line.

7. The semiconductor wafer of claim 1 further including:
an on-chip circuit disposed within the first IC;
wherein the first metal conductor couples to the on-chip circuit.
a test pad electrically coupled to provide a power signal to the first metal conductor.

8. The semiconductor wafer of claim 1 further including:
an on-chip circuit disposed within the first IC;
a switch disposed within the scribe line to selectably couple to the first metal conductor to the on-chip circuit; and
a test pad electrically coupled to provide a power signal to the first metal conductor.

9. The semiconductor wafer of claim 1 further including:
a second metal conductor extending within the scribe line electrically coupled to the at least one of the first and second ICs;
a test circuit having a circuit component disposed within the at least one of the first and second ICs;
a first test pad electrically coupled to provide a voltage power signal to the first metal conductor; and
a second test pad electrically coupled to provide a reference signal to the second metal conductor;
wherein the first metal conductor is coupled to provide a voltage power signal to the test circuit; and
wherein the second metal conductor is coupled to provide a reference signal to the test circuit.

10. The semiconductor wafer of claim 1 further including:
a second metal conductor extending within the scribe line electrically coupled to the at least at least one of the first and second ICs;
a third metal conductor extending within the scribe line electrically coupled to the at least at least one of the first and second ICs; and
test circuit having a circuit component disposed within the at least one of the first and second ICs;
wherein the first conductor is electrically coupled to provide a voltage power signal to the test circuit;
wherein the second conductor is electrically coupled to provide a reference signal to the test circuit; and
wherein the third conductor is electrically coupled to provide a control signal to the test circuit.

11. The semiconductor wafer of claim 1, further including:
a switch configured to selectably disconnect at least one of the first and second ICs from the first conductor;

12. The semiconductor wafer of claim 1, further including:
a switch configured to selectably disconnect at least one of the first and second ICs from the first conductor;
wherein the switch is disposed within the scribe line.

13. The semiconductor wafer of claim 1, further including:
a switch configured to receive a switch control signal from one of the first and second ICs to selectably disconnect the other of the first and second ICs from the first conductor.

14. A semiconductor wafer comprising:
a plurality of integrated circuits (ICs) arranged in a two dimensional grid;
a plurality of scribe lines each extending between multiple ICs in the grid; and
a first conductor extending within at least one first scribe line adjacent to multiple ICs.

15. The semiconductor wafer of claim 14 further including:
a test pad electrically coupled to provide a signal to the first conductor;
wherein the test pad is disposed between ICs within the grid.

16. The semiconductor wafer of claim 14 further including:
a test pad electrically coupled to provide a signal to the first conductor;
wherein the test pad is disposed at a perimeter of the grid.

17. The semiconductor wafer of claim 14 further including:
a plurality of on-chip circuits each disposed within a different one of the multiple ICs;
wherein the first conductor is coupled to provide a signal to each of the on-chip circuits.

18. A method of wafer-level testing of integrated circuits comprising:
conducting an electronic signal between a metal conductor within a scribe line and an integrated circuit.

19. The method of claim 18 further including:
conducting the electronic signal on a metal conductor within a scribe line between a test pad and an integrated circuit.

20. The method of claim 18 further including:
conducting the electronic signal on a metal conductor within a scribe line between a first integrated circuit and a second integrated circuit.
